(19) United States
(12) Patent Application Publication
(10) Pub. No.: US 2023/0037057 A1
(43) Pub. Date: Feb. 2, 2023

(54) UV-PATTERNED CONDUCTIVE POLYMER ELECTRODE FOR QLED

(71) Applicant: Sharp Display Technology Corporation, Kameyama City (JP)

(72) Inventors: HYWEL HOPKIN, Oxford (GB); VALERIE BERRYMAN-BOUSQUET, Chipping Norton (GB); ANDREW KAY, Oxford (GB); ALEX YUDIN, Abingdon (GB); ALESSANDRO MINOTTO, London (GB)

(21) Appl. No.: 17/390,246

(22) Filed: Jul. 30, 2021

(51) Int. Cl. H01L 51/50; H01L 27/32; H01L 51/00; H01L 51/52

(52) U.S. Cl. CPC H01L 51/502; H01L 27/3246; H01L 51/0037; H01L 51/5218; H01L 51/5056; H01L 51/5234; H01L 27/323; H01L 2251/5315; H01L 51/5088

(57) ABSTRACT

A top-emitting pixel device is disclosed. The pixel device may include a reflective bottom electrode disposed over a substrate, a first charge transport layer disposed over the reflective bottom electrode, an emissive layer disposed over the first charge transport layer, and a second charge transport layer disposed over the emissive layer. Further, the pixel device may include a patterned transparent polymer electrode disposed over the second charge transport layer and extending laterally to cover an emissive area of the top-emitting pixel device, and a patterned auxiliary electrode disposed at least partially over the patterned transparent polymer electrode outside of the emissive area of the top-emitting pixel device to make direct electrical contact with the patterned transparent polymer electrode.

### FIELD

The present disclosure generally relates to quantum-dot light-emitting diodes (QLEDs), and in particular relates to patterning of one or more layers of a QLED (e.g., such that the QLED provides improved electrical characteristics).

### BACKGROUND

QLEDs represent an emerging emissive display technology with the potential to outperform organic light-emitting diodes (OLEDs) while being less expensive to fabricate due to the ability to solution-process the different layers of the QLED. QLED structures may be carefully designed to optimize light extraction to render the QLEDs as efficient as possible. The most efficient designs are typically top-emitting QLEDs having transparent top electrodes. No “perfect” solution for a transparent top electrode currently exists, but several attempts at such a solution have been made using graphene, conductive nanowires, and conductive nanoparticles. However, many of these approaches are associated with one or more poor performance characteristics, including, but not limited to, reduced transparency and low refractive index. Further, at least some of these solutions provide reduced protection for, or result in increased damage to, lower QLED layers during the manufacturing process.

For example, typical top-emitting QLED devices may employ a transparent electrode fabricated from indium tin oxide (ITO). ITO is also typically used as a transparent electrode in liquid-crystal display (LCD) and bottom-emitting OLED technology. However, deposition of ITO usually involves high-energy processing that may be destructive to the underlying QLED layers. ITO may be sputtered atop an electron transport layer (ETL) of a QLED under particular conditions. However, without a high-temperature bake operation, which is not possible with QLED structures, the sputtered ITO layer may possess undesirably low transparency.

### SUMMARY

The present disclosure is directed to QLEDs in which one or more layers thereof are patterned (e.g., to provide improved electrical characteristics).

In accordance with one aspect of the present disclosure, a top-emitting pixel device may include a reflective bottom electrode disposed over a substrate, a first charge transport layer disposed over the reflective bottom electrode, an emissive layer disposed over the first charge transport layer, and a second charge transport layer disposed over the emissive layer. Further, the pixel device may include a patterned transparent polymer electrode disposed over the second charge transport layer and extending laterally to cover an emissive area of the top-emitting pixel device, and a patterned auxiliary electrode disposed at least partially over the patterned transparent polymer electrode outside of the emissive area of the top-emitting pixel device to make direct electrical contact with the patterned transparent polymer electrode.

In an implementation of the first aspect, the patterned transparent polymer electrode may include a conductive polymer that is crosslinked by an ultraviolet-activated (UV-activated) crosslinking agent.

In another implementation of the first aspect, the patterned transparent polymer electrode may include a conductive polymer within a crosslinked matrix. In an example, the crosslinked matrix may be formed using a crosslinking agent, a photoinitiator, and a monomer. In another example, the crosslinked matrix may be formed using a UV-activated crosslinking agent and a monomer. In another example, the crosslinked matrix may be formed using a UV-activated crosslinking agent.

In another implementation of the first aspect, the top-emitting pixel device may further include a pixel-defining structure at least partially surrounding the emissive layer, the patterned transparent polymer electrode may extend partially over the pixel-defining structure, and the patterned auxiliary electrode may extend over a portion of the patterned transparent polymer electrode and the pixel-defining structure. In an example, the pixel-defining structure may include a bank structure separating at least the emissive layer of the top-emitting pixel device from an emissive layer of a second pixel device.

In another implementation of the first aspect, the reflective bottom electrode may include an anode, the first charge transport layer may include a hole transport layer, the second charge transport layer may include an electron transport layer, and a combination of the patterned transparent polymer electrode and the patterned auxiliary electrode may include a cathode. In an example, the patterned transparent polymer electrode of the cathode may have an energy level in a range of −3.8 electron-volts (eV) to −4.7 eV.

In another implementation of the first aspect, the reflective bottom electrode may include a cathode, the first charge transport layer may include an electron transport layer, the second charge transport layer may include a hole transport layer, and a combination of the patterned transparent polymer electrode and the patterned auxiliary electrode may include an anode. In an example, the patterned transparent polymer electrode of the anode may have an energy level in a range of −4.7 eV to −5.6 eV.

In accordance with a second aspect of the present disclosure, a display device may include a substrate, a pixel-defining structure defining a plurality of pixel regions over the substrate, and an array of top-emitting pixel devices positioned over the substrate. Each of the top-emitting pixel devices may be located within a corresponding one of the plurality of pixel regions. Also, each of the top-emitting pixel devices may include a reflective bottom electrode disposed over the substrate, a first charge transport layer disposed over the reflective bottom electrode, an emissive layer disposed over the first charge transport layer, and a second charge transport layer disposed over the emissive layer. Each of the top-emitting pixel devices may further include a patterned transparent polymer electrode disposed over the second charge transport layer and extending laterally to cover an emissive area of the top-emitting pixel device, and a patterned auxiliary electrode disposed at least partially over the patterned transparent polymer electrode outside of the emissive area of the top-emitting pixel device to make direct electrical contact with the patterned transparent polymer electrode. The patterned transparent polymer electrodes and the patterned auxiliary electrodes of the display device may form a plurality of electrically separated conductive regions, where each of the electrically separated conductive regions forms an electrode for at least one of the top-emitting pixel devices.

In an implementation of the second aspect, at least one of the electrically separated conductive regions may form an electrode for more than one of the top-emitting pixel devices.

In another implementation of the second aspect, at least two of the electrically separated conductive regions may operate as in-cell touch panel electrodes.

In another implementation of the second aspect, the in-cell touch panel electrodes may include a first portion of the electrically separated conductive regions operating as in-cell touch panel signal electrodes, and a second portion of the electrically separated conductive regions operating as in-cell touch panel sensing electrodes.

In accordance with a third aspect of the present disclosure, a top-emitting pixel device may include a reflective bottom anode disposed over a substrate, a hole injection layer disposed over the reflective bottom anode, a hole transport layer disposed over the hole injection layer, an emissive layer disposed over the hole transport layer, an electron transport layer disposed over the emissive layer and a pixel-defining structure at least partially surrounding the top-emitting pixel device, and a transparent cathode disposed over the electron transport layer. The hole injection layer may include a patterned transparent conductive polymer that is electrically separated from the electron transport layer.

In an implementation of the third aspect, the patterned transparent conductive polymer may be crosslinked via an ultraviolet-activated crosslinking agent.

In another implementation of the third aspect, the hole injection layer, the hole transport layer, and the emissive layer may be patterned to prevent covering the pixel-defining structure.

### BRIEF DESCRIPTION OF DRAWINGS

Aspects of the example disclosure are best understood from the following detailed description when read with the accompanying figures. Various features are not drawn to scale. Dimensions of various features may be arbitrarily increased or reduced for clarity of discussion.

FIG. 1 is a cross-sectional side view of a QLED pixel structure having a patterned transparent polymer electrode that is partially overlapped by an auxiliary electrode, in accordance with an example implementation of the present disclosure.

FIGS. 2A and 2B are energy level diagrams depicting energy levels for various layers of a QLED, in accordance with an example implementation of the present disclosure.

FIGS. 3A and 3B provide a process diagram for creating a patterned transparent polymer electrode that is partially overlapped by an auxiliary electrode, in accordance with an example implementation of the present disclosure.

FIG. 4 is a cross-sectional top view of top electrode structures for multiple sets of QLED subpixels, in accordance with an example implementation of the present disclosure.

FIG. 5 is a top view of a top electrode structure employable for a touch display, in accordance with an example implementation of the present disclosure.

FIG. 6 is a cross-sectional side view of a QLED pixel structure having a patterned hole injection layer and a patterned combined hole transport/emissive layer, in accordance with an example implementation of the present disclosure.

### DESCRIPTION

The following description contains specific information pertaining to exemplary implementations in the present disclosure. The drawings and their accompanying detailed description are directed to exemplary implementations. However, the present disclosure is not limited to these exemplary implementations. Other variations and implementations of the present disclosure will occur to those skilled in the art. Unless noted otherwise, like or corresponding elements in the figures may be indicated by like or corresponding reference numerals. Moreover, the drawings and illustrations are generally not to scale and are not intended to correspond to actual relative dimensions.

For consistency and ease of understanding, like features are identified (although, in some examples, not shown) by numerals in the exemplary figures. However, the features in different implementations may be different in other respects, and therefore will not be narrowly confined to what is shown in the figures.

The phrases “in one implementation” and “in some implementations” may each refer to one or more of the same or different implementations. The term “coupled” is defined as connected, whether directly or indirectly via intervening components, and is not necessarily limited to physical connections. The term “comprising” means “including, but not necessarily limited to” and specifically indicates open-ended inclusion or membership in the described combination, group, series, and equivalent.

Additionally, any two or more of the following paragraphs, (sub-)bullets, points, actions, behaviors, terms, alternatives, examples, or claims described in the following disclosure may be combined logically, reasonably, and properly to form a specific method. Any sentence, paragraph, (sub-)bullet, point, action, behavior, term, or claim described in the following disclosure may be implemented independently and separately to form a specific method. Dependency, e.g., “according to”, “more specifically”, “preferably”, “in one embodiment”, “in one implementation”, “in one alternative”, etc., in the following disclosure refers to just one possible example which would not restrict the specific method.

For explanation and non-limitation, specific details, such as functional entities, techniques, protocols, and standards, are set forth for providing an understanding of the described technology. In other examples, detailed description of well-known methods, technologies, systems, and architectures are omitted so as not to obscure the description with unnecessary details.

Also, while certain directional references (e.g., top, bottom, up, down, height, width, and so on) are employed in the description below and appended claims, such references are utilized to provide guidance regarding the positioning and dimensions of various elements relative to each other and are not intended to limit the orientation of the various embodiments to those explicitly discussed herein.

Various embodiments of QLED structures, as described in greater detail below, may include one or more patterned layers (e.g., a patterned transparent top electrode, a patterned auxiliary electrode, a patterned hole injection layer, etc.) to provide enhanced electrical properties, and thus increased display performance. Further, in some embodiments, use of these patterned layers may be extended to efficiently incorporate touch input functionality into the associated display.

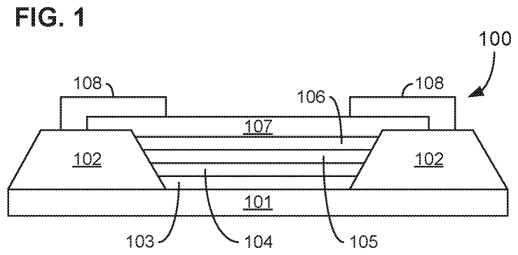

FIG. 1 is a cross-sectional side view of a top-emitting QLED pixel structure 100 having a patterned transparent polymer electrode 107 that is partially overlapped by an auxiliary electrode 108, in accordance with an example implementation of the present disclosure. As depicted in FIG. 1, pixel structure 100 may include a bottom reflective electrode 103 in electrical contact with a driving circuit on a substrate 101. The driving circuit may be a thin-film transistor (TFT) circuit. The emission region of pixel structure 100 may be defined by insulating banks 102, or pixel-defining layers, patterned around bottom reflective electrode 103. An emissive layer (EML) 105 is positioned between bottom reflective electrode 103 and patterned transparent polymer electrode 107. Pixel structure 100 may also include a first charge transport layer (CTL) 104 between EML 105 and bottom reflective electrode 103 and a second CTL 106 between EML 105 and patterned transparent polymer electrode 107. For a “standard” or “normal” pixel structure 100, second CTL 106 may include an electron transport layer (ETL) and/or an electron injection layer (EIL), while first CTL 104 may include a hole transport layer (HTL) and/or a hole injection layer (HIL). In such examples, bottom reflective electrode 103 may serve as an anode, while patterned transparent polymer electrode 107 may operate as a cathode for (normal) pixel structure 100. In an “inverted” pixel structure 100, second CTL 106 may include an HTL and/or an HIL, while first CTL 104 may include an ETL and/or an EIL. In such implementations, bottom reflective electrode 103 may serve as a cathode, while patterned transparent polymer electrode 107 may operate as an anode for (inverted) pixel structure 100. In some embodiments, auxiliary electrode 108 may be metallic, and may be non-transparent.

In some embodiments, patterned transparent polymer electrode 107 may be deposited and patterned on top of second CTL 106. As illustrated in FIG. 1, polymer electrode 107 may cover (e.g., at a minimum) the width of an emissive area of pixel structure 100, such as an area between banks 102. Polymer electrode 107 may extend over one or more banks 102 and at least partially cover a top of banks 102. Auxiliary electrode 108 may be deposited and patterned on top of banks 102 (e.g., in the non-emissive regions of pixel structure 100). Auxiliary electrode 108 may overlap patterned transparent polymer electrode 107 so that the materials of polymer electrode 107 and auxiliary electrode 108 are in electrical contact. Auxiliary electrode 108 may extend over bank 102 to an edge of the emissive area.

More particularly, in some implementations of pixel structure 100, transparent polymer electrode 107 may be an ultraviolet-patterned (UV-patterned) conductive polymer, and auxiliary electrode 108 may be a UV-patterned metal. Patterned transparent polymer electrode 107 (e.g., crosslinked with a UV-activated crosslinking agent) may span to at least cover the emissive area of pixel structure 100, but may be patterned so that it is not continuous over bank 102 that surrounds and defines the emissive area. Auxiliary electrode 108 may be patterned such that auxiliary electrode 108 may only be present in the non-emissive region on bank 102. In some examples, auxiliary electrode 108 may extend over bank 102 to the edge of the emissive area or may be non-continuous over bank 102. In some implementations, at least one region may exist where patterned transparent polymer electrode 107 overlaps with auxiliary electrode 108, thus forming a direct electrical contact therebetween that allows electrical current to spread from auxiliary electrode 108 through polymer electrode 107 and across pixel structure 100.

The choice of which conductive polymer to employ for a given pixel structure may be affected by the energy level (or, alternatively, work function) of the particular material to be used. In many cases, the energy level may vary considerably with small changes to a conductive polymer, such as poly(3,4-ethylenedioxythiophene) (PEDOT) (e.g., PEDOT complexed with polystyrene sulfonate, or PEDOT:PSS). For example, different types of PEDOT dispersions may result in polymer films with different energy levels. Moreover, additives used in the dispersions, such as to help with solubility or conductivity, may have a large effect on the energy level. Therefore, a given conductive polymer may be more suitable for an inverted pixel structure 100 or a standard pixel structure 100.

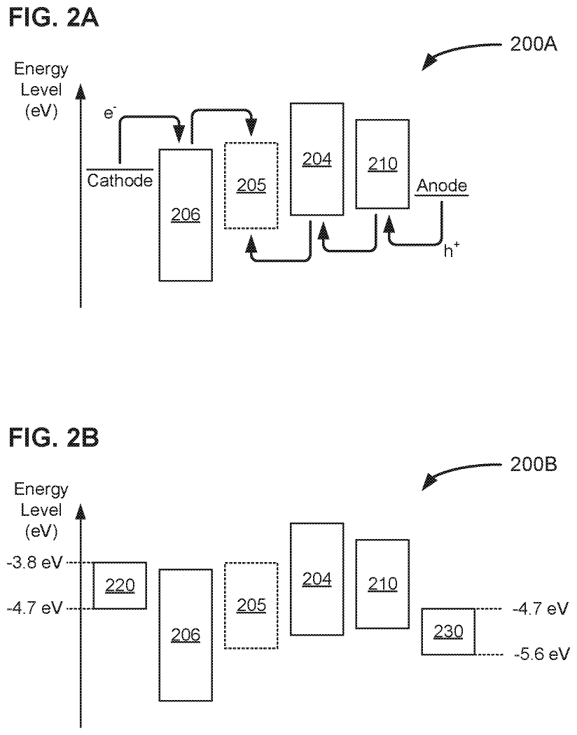

FIGS. 2A and 2B are energy level diagrams 200A and 200B, respectively, depicting energy levels for various layers of pixel structure 100, in accordance with an example implementation of the present disclosure. Illustrated in FIG. 2A are the energy bands for several of the layers of pixel structure 100, such as an ETL energy band 206 for an ETL, an EML energy band 205 for EML 105, an HTL energy band 204 for an HTL, and an HIL energy band 210 for an HIL. Also shown in FIG. 2A are an example energy level for a cathode (e.g., from which electrons may pass through the ETL to EML 105) and an example energy level for an anode (e.g., from which holes may pass through the HIL and HTL to EML 105). To facilitate acceptable performance of pixel structure 100, compatible energy level alignment between the layers is desirable for the electrons (e⁻) being injected from the cathode into EML 105 along a “top” of energy diagram 200A, and for the holes (h⁺) being injected from the anode into EML 105 along a “bottom” of energy diagram 200A. In some implementations, desirable energy levels, in the presence of a forward-bias voltage across pixel structure 100, may facilitate transfer of electrons and holes from the cathode and anode, respectively, to EML 105 (e.g., via relatively small energy barriers), while providing some resistance to the electrons and holes passing beyond EML 105 (e.g., via relatively large energy barriers).

FIG. 2B provides an energy level diagram 200B similar to energy level diagram 200A while depicting example ranges (as opposed to single values) of energy levels for an anode and a cathode. For a cathode, in some implementations, a transparent conductive polymer may have an energy level in the range of −3.8 electron-volts (eV)>φ>−4.7 eV. For an anode, a transparent conductive polymer may have an energy level in the range of −4.7 eV>φ>−5.6 eV. In the case of PEDOT, for example, one grade of PEDOT (e.g., PH1000 of the Clevios™ PEDOT:PSS product line by Heraeus of Hanau, Germany) may be a suitable option for an inverted pixel structure 100, in which top transparent polymer electrode 107 serves as an anode. For a standard pixel structure 100, another grade of PEDOT (e.g., HTL Solar 3 of the Clevios' PEDOT:PSS product line by Heraeus of Hanau, Germany) may be a suitable option for a top transparent polymer electrode 107 serving as a cathode. Other examples for the transparent conductive polymer serving as an anode or a cathode are also possible.

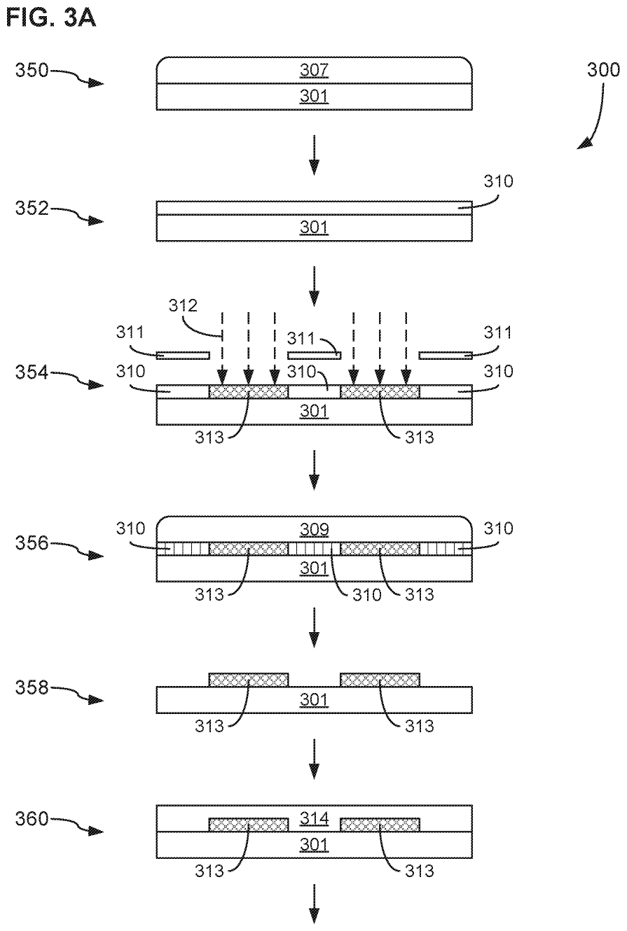

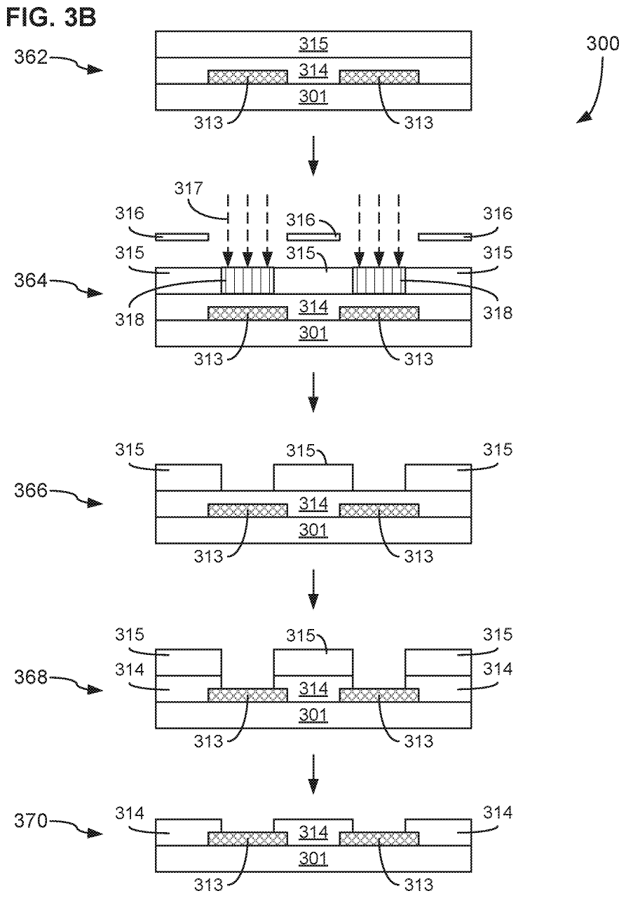

FIGS. 3A and 3B provide a process diagram of a method 300 for creating a patterned transparent polymer electrode that is partially overlapped by an auxiliary electrode, in accordance with an example implementation of the present disclosure. Beginning with FIG. 3A, at operation 350, a polymer dispersion 307 from which the patterned transparent polymer electrode (e.g., patterned transparent polymer electrode 107 of FIG. 1) is to be created (e.g., by way of direct UV patterning) is processed onto a substrate 301. In some implementations, substrate 301 may include one or more layers of pixel structure 100 (e.g., substrate 101, bottom reflective electrode 103, first CTL 104, EML 105, and second CTL 106) to be located under patterned transparent polymer electrode 107.

Polymer dispersion 307 may include a conductive polymer (e.g., PEDOT) dissolved in a solvent. In some implementations, polymer dispersion may include PEDOT:PSS dissolved in water. In other implementations, PEDOT may be employed with other complexing agents aside from PSS to facilitate dispersion of the PEDOT in other solvents. Other combinations of a conductive polymer and a solvent are also possible. Based on how the conductive polymer is prepared and dispersed in polymer dispersion 307, the resulting transparent polymer electrode may possess any of a range of different conductivities and work functions, or energy levels. Further, in some implementations, the solvent within which the conductive polymer is dispersed may affect which materials may reside adjacent thereto within pixel structure 100.

In some implementations, a crosslinking agent may be mixed with polymer dispersion 307 prior to processing onto substrate 301. The crosslinking agent may include a UV-activated crosslinking agent that forms links directly between polymer chains of the conductive polymer. In some implementations, the UV-activated crosslinking agent may include UV-sensitive compounds that form highly reactive species that insert into carbon-hydrogen (C—H) bonds of the conductive polymer. Examples of such compounds may include the families of bis-azide or poly-azide molecules.

In other embodiments, the crosslinking agent may form a crosslinked matrix around individual components of the conductive polymer. In some implementations, the crosslinked matrix may be formed from one or more of a crosslinking agent, a monomer, a photoinitiator, or a UV-activated crosslinking agent. For example, the crosslinked matrix may be formed from a crosslinking agent, a monomer, and a photoinitiator. In yet another example, the crosslinked matrix may be formed from a UV-activated crosslinking agent and a monomer, or may be formed from a UV-activated crosslinker without a monomer.

At operation 352 of method 300, the solvent of polymer dispersion 307 may evaporate, leaving a dried, continuous polymer film 310 atop substrate 301. At operation 354, a photomask 311 may be configured and positioned over polymer film 310 such that selected areas of polymer film 310 may exposed to UV light 312 through photomask 311. In the regions exposed to UV light 312, the crosslinking agent may form bonds with the polymer chains of the conductive polymer, or may form a crosslinked matrix, such that the exposed regions of polymer film 310 may become a patterned crosslinked polymer film 313. Consequently, patterned crosslinked polymer film 313 may become less soluble than those regions of polymer film 310 that were not exposed to UV light 312. At operation 356, the structure may be washed with a compatible solvent 309, thus washing away the more soluble regions of polymer film 310. Consequently, at operation 358, removing solvent 309 may leave patterned crosslinked polymer film 313 atop substrate 301 to serve as patterned transparent polymer electrode 107 (as shown in FIG. 1).

At operations 360 through 370, a metal wet-etch process may be employed to pattern an auxiliary electrode atop patterned crosslinked polymer film 313, which may be resilient to aqueous processing. Specifically, at operation 360, for example, metal 314 may be deposited (e.g., via thermal evaporation, sputtering, or the like) atop patterned crosslinked polymer film 313. Continuing with FIG. 3B, at operation 362, photoresist 315 may be deposited atop metal 314. At operation 364, photoresist 315 may be patterned using photolithography by exposing portions 318 of photoresist 315 to light 317 through a photomask 316. At operation 366, the exposed portions 318 of photoresist 315 may be removed, thus exposing corresponding regions of metal 314. At operation 368, the exposed regions of metal 314 may be chemically etched, where the crosslinked nature of patterned crosslinked polymer film 313 renders polymer film 313 resilient to the chemical etching process. At operation 370, the remaining photoresist 315 may be removed, resulting in patterned crosslinked polymer film 313, serving as patterned transparent polymer electrode 107 (as shown in FIG. 1), being placed in direct contact with the remaining regions of metal 314, serving as patterned auxiliary electrode 108 of pixel structure 100, with reference to FIG. 1.

In some QLED manufacturing processes, some conductive polymers are dispersed in solvents which are not compatible with underlying QLED structures, which are often fabricated using “orthogonal” solvent solution processing (e.g., each solvent used in one layer does not re-dissolve and/or re-disperse the layer below). For example, PEDOT:PSS dispersions are typically dispersed in water, and PEDOT dispersions are typically dispersed in other solvents such as methoxybenzene, both of which may cause defects in underlying layers when deposited on a QLED stack.

Thus, to enable flexibility with respect to which solvents may be used for depositing conductive polymers (e.g., PEDOT or PEDOT:PSS) on QLED structures, one or more, or potentially all, of the underlying layers (e.g., substrate 301, which may include one or more layers of pixel structure 100) located below the conductive polymer layer (e.g., patterned crosslinked polymer film 313 or patterned transparent polymer electrode 107) may be made more robust via crosslinking of some form. In some implementations, several crosslinking techniques may be used for those layers, such as forming a crosslinked matrix around an active layer, using bifunctional crosslinkers that crosslink to specific functional groups (e.g., amine groups or carbonyl groups) of an active layer, and nonselective (or photoreactive) crosslinkers that insert randomly into sites on organic chains of an active layer.

For example, the ETL (e.g., serving as first CTL 104 or second CTL 106), which may include magnesium zinc oxide (MgZnO), may be mixed with a polymer (e.g., polyvinylpyrrolidone (PVP)) to improve QLED performance. In some implementations, this polymer may be crosslinked with the addition of a crosslinking agent to form a polymer matrix around the ETL.

Regarding EML 105, by adding a crosslinker, the ligands of adjacent quantum dots may become linked together, making the resulting QD film insoluble. Alternatively, the QDs may be mixed with a crosslinkable HTL that may fix the QDs in place when crosslinked. Crosslinkable HTLs may include OTPD (e.g., N4,N4′-Bis(4-(6-((3-ethyloxetan-3-yl)methoxy)hexyl)phenyl)-N4,N4′-diphenylbiphenyl-4,4′-diamine) and TFB (e.g., poly(9,9-dioctylfluorene-alt-N-(4-sec-butylphenyl)-diphenylamine).

Moreover, in addition to the layers discussed above, top-emitting QLED pixel structure 100 of FIG. 1 may also include one or both of an electron blocking layer (EBL) and/or a hole blocking layer (HBL), each of which may be a thin polymer layer employed to improve charge balance. In top-emitting QLED pixel structure 100, the EBL may be situated between the ETL and EML 105, or between EML 105 and the HTL. Similarly, the HBL may also be situated between the ETL and EML 105, or between EML 105 and the HTL. Either or both of the EBL and the HBL may be readily crosslinked via the addition of a crosslinking agent that directly links the polymer chains of the EBL or HBL.

By crosslinking one or more layers of top-emitting QLED pixel structure 100 underlying patterned transparent polymer electrode 107, pixel structure 100 may be made more stable to processing in various solvents. In some implementations, the crosslinking process for each layer may be employed to pattern that layer in a similar way as described for patterned transparent polymer electrode 107, as described above. Alternatively, with the exception of EML 105 and patterned transparent polymer electrode 107, all remaining crosslinked layers may be common (e.g., continuous across pixels).

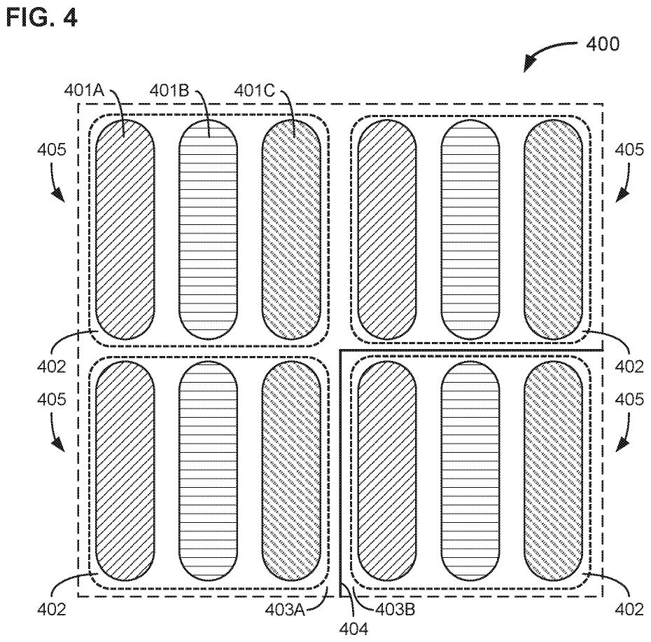

As is discussed in greater detail below, multiple patterned transparent polymer electrodes 107 and patterned auxiliary electrodes 108 of a QLED display may be configured in various ways, such as to support additional functionality integrated with the display. For example, FIG. 4 is a cross-sectional top view of top electrode structures for multiple sets of QLED subpixels 401A-401C of a QLED display 400, in accordance with an example implementation of the present disclosure. More specifically, a set of four pixels 405 of QLED display 400 is depicted in FIG. 4, where each pixel 405 may include three subpixels: a red subpixel 401A, a green subpixel 401B, and a blue subpixel 401C. Further, each subpixel 401A-401C may be configured as pixel structure 100 of FIG. 1. Moreover, in some implementations, all QLED layers beneath the top electrode (e.g., including patterned transparent polymer electrode 107 and auxiliary electrode 108), with the exception of EML 105 and bottom reflective electrode 103, may be common to each pixel 405.

FIG. 4 demonstrates how auxiliary electrodes 403A and 403B and patterned transparent polymer electrodes 402, in some implementations, may be patterned so that the resulting top electrode is electrically connected between some pixels 405 (e.g., the top-left, top-right, and bottom-left pixels 405 of FIG. 4), and isolated between others (e.g., the bottom-right pixel 405 of FIG. 4). In this example, each patterned transparent polymer electrode 402 is patterned (as shown by dotted lines in FIG. 4) to be common to, and covering, each corresponding set of three subpixels 401A-401C. In other examples, however, each patterned transparent polymer electrode 402 may be configured to cover just one subpixel 401A-401C, or some array of subpixels 401A-401C.

Partially covering patterned transparent polymer electrodes 402 are two auxiliary electrodes 403A and 403B that may be patterned such that they do not cover the emissive regions of subpixels 401A-401C. A first auxiliary electrode 403A may cover, and thus may be directly connected to, portions of each patterned transparent polymer electrode 402 corresponding to the top-left, top-right, and bottom-left pixels 405. A second auxiliary electrode 403B may cover and be directly connected to portions of patterned transparent polymer electrode 402 corresponding to the bottom-right pixel 405. Auxiliary electrodes 403A and 403B may be electrically isolated from each other, as shown by way of a boundary 404 in FIG. 4, thus indicating a region where neither patterned transparent polymer electrodes 402 nor auxiliary electrodes 403A and 403B are located.

In some implementations, patterning the top electrodes of a QLED display in such a manner, as depicted in FIG. 4, may facilitate efficient use of the top electrodes for additional functionality associated with the display in addition to the operation of the QLEDs. For example, a QLED display may be configured with a top electrode structure that is separated into a number of isolated conductive regions (e.g., as discussed above) of any desired pattern, shape, and/or size to implement an in-cell touch top electrode design. In some examples, in-cell touch technology may provide an advantage over on-cell touch technology, which may require several additional layers and circuitry patterned on top of the QLED display, thus making the overall display thicker, and thus less space-efficient. Further, in the case of a flexible substrate, the additional layers of on-cell touch technology may reduce the physical flexibility of the display.

Depending on the design, the in-cell touch top electrode may be used to enable self-capacitance touch sensing, mutual capacitance touch sensing, haptic feedback touch, and/or force sensitive touch. The conductive regions may act as sensing electrodes, signal electrodes, and/or floating electrodes. In some implementations, conductive bridging structures may be included where two separate conductive regions cross. Also, in some examples, an additional electrode may be applied in a plane separate from a plane containing the in-cell top electrodes to enable additional non-display functionality.

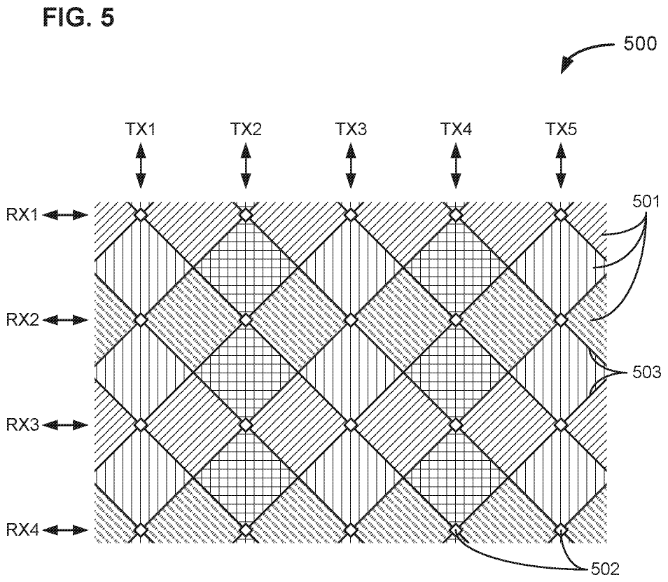

FIG. 5 is a top view of a top electrode structure 500 employable for a touch display (e.g., an in-cell touch display employing a mutual capacitance design), in accordance with an example implementation of the present disclosure. As depicted in FIG. 5, top electrode structure 500 may be configured into multiple signal electrodes TX1, TX2, TX3, TX4, and TX5 extending vertically, and multiple sensing electrodes RX1, RX2, RX3, and RX4 extending horizontally. Each electrode TX1-TX5 and RX1-RX4 may be configured using multiple diamond-shaped regions 501 and may be isolated from other electrodes by way of boundaries 503 formed in top electrode structure 500 by patterning the transparent polymer electrodes and the auxiliary electrodes of multiple pixel structures 100, as described above. In some examples, boundaries 503 may be formed along bank structures (e.g., non-emissive regions) of the QLED display. In some implementations, for a sensing electrode RX1-RX4 to remain connected when crossing a signal electrode TX1-TX5, a bridge connection 502 (e.g., a metallic connection lying in a separate layer from diamond-shaped regions 501) may be employed to bridge over the intervening signal electrode TX1-TX5.

While the above discussion focusses on the use of direct UV-patterning of conductive polymers, such as PEDOT, for a top electrode of a pixel structure, other layers of the pixel structure may benefit from such a technology. For example, a conventional top-emitting QLED device may include a semi-transparent thin metal top electrode. Large-area, solution-based deposition techniques such as spin coating, blade coating, slot-die coating, or spray coating are generally unable to pattern underlying QLED layers without additional, and sometimes complex, processing. Ink-jet printing may be used to pattern layers at low resolutions, but such patterning technology currently faces challenges at high resolution. In general, QLED layers are deposited across an entirety of the display such that each layer is continuous. The exception to this general rule is the emissive layer, which is patterned to form the individual subpixels of the QLED display.

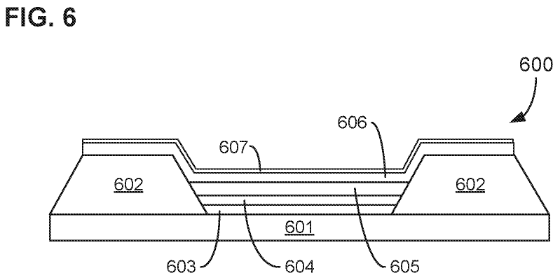

FIG. 6 is a cross-sectional side view of a QLED pixel structure 600 having a patterned hole injection layer (HIL) 604 and a patterned combined hole transport/emissive layer (HTL/EML) 605, in accordance with an example implementation of the present disclosure. As depicted in FIG. 6, pixel structure 600 is a standard-type top-emitting QLED, with a bottom reflective electrode 603 atop a substrate 601 and between banks 602, where bottom reflective electrode 603 operates as an anode. Atop bottom reflective electrode 603 lies, in order, patterned HIL 604 and patterned combined HTL/EML 605. Over patterned combined HTL/EML 605 and banks 602 may lie an unpatterned ETL 606 and an unpatterned, substantially transparent top electrode 607 (e.g., made of a thin layer of metal, such as silver).

In some conventional QLED displays, an HIL may not be patterned (e.g., due to typical patterning processes possibly inflicting damage on conventional HIL materials), and thus may lie continuously across both the bottom electrodes and banks of a display device. Oppositely, a combined HTL/EML of conventional displays may be patterned (e.g., using a patternable HTL matrix or a photolithography-based lift-off process) so that they are restricted primarily within the emissive area. Consequently, in regions (e.g., on the banks) where no combined EML layer in the structure is present, the ETL (lying atop the combined HTL/EML) and the HIL may make direct electrical contact. Accordingly, if the HIL possesses reasonable conductivity, then this contact may create a path for undesirable current leakage between the top and bottom electrodes of the conventional QLED. Consequently, by patterning HIL 604 in pixel structure 600, as illustrated in FIG. 6, no such path for current leakage between bottom reflective electrode 603 and top electrode 607 may be created.

In some implementations, to render HIL 604 of pixel structure 600 patternable, HIL 604 may include a UV-patterned conductive polymer, such as a PEDOT based-material mixed with a crosslinking agent. In some implementations, the PEDOT material may have a deep energy level. Examples of such a PEDOT material may include PH1000 or AI4083 (e.g., another member of the Clevios™ PEDOT:PSS product line by Heraeus of Hanau, Germany), either of which may be dispersed in water as a solution. Accordingly, a water-soluble crosslinking agent may be included in the dispersion to facilitate use of water as a solvent. An example of such a crosslinking agent is a bis-azide salt, such as disodium 4,4′-Diazidostilbene-2,2′-disulfonate. Constructing HIL 604 in such a manner may facilitate patterning of HIL 604, and well as render HIL 604 more resilient to harsh processing (e.g., EML patterning processes), thus minimizing damage to HIL 604 during manufacturing of the display.

Embodiments of the present disclosure are applicable to many display devices to permit display devices of high resolution with effective threshold voltage compensation and true black performance. Examples of such devices include televisions, mobile phones, personal digital assistants (PDAs), tablet and laptop computers, desktop monitors, digital cameras, and like devices for which a high-resolution display is desirable.

From the above discussion, it is evident that various techniques can be utilized for implementing the concepts of the present disclosure without departing from the scope of those concepts. Moreover, while the concepts have been described with specific reference to certain implementations, a person of ordinary skill in the art would recognize that changes can be made in form and detail without departing from the scope of those concepts. As such, the disclosure is to be considered in all respects as illustrative and not restrictive. It should also be understood that the present disclosure is not limited to the particular described implementations, but that many rearrangements, modifications, and substitutions are possible without departing from the scope of the present disclosure.

What is claimed is:

1. A top-emitting pixel device comprising:
a reflective bottom electrode disposed over a substrate;
a first charge transport layer disposed over the reflective bottom electrode;
an emissive layer disposed over the first charge transport layer;
a second charge transport layer disposed over the emissive layer;
a patterned transparent polymer electrode disposed over the second charge transport layer and extending laterally to cover an emissive area of the top-emitting pixel device; and
a patterned auxiliary electrode disposed at least partially over the patterned transparent polymer electrode outside of the emissive area of the top-emitting pixel device to make direct electrical contact with the patterned transparent polymer electrode.

2. The top-emitting pixel device of claim 1, wherein the patterned transparent polymer electrode comprises a conductive polymer that is crosslinked by an ultraviolet-activated (UV-activated) crosslinking agent.

3. The top-emitting pixel device of claim 1, wherein the patterned transparent polymer electrode comprises a conductive polymer within a crosslinked matrix.

4. The top-emitting pixel device of claim 3, wherein the crosslinked matrix is formed using a crosslinking agent, a photoinitiator, and a monomer.

5. The top-emitting pixel device of claim 3, wherein the crosslinked matrix is formed using a UV-activated crosslinking agent and a monomer.

6. The top-emitting pixel device of claim 3, wherein the crosslinked matrix is formed using a UV-activated crosslinking agent.

7. The top-emitting pixel device of claim 1, wherein:
the top-emitting pixel device further comprises a pixel-defining structure at least partially surrounding the emissive layer;
the patterned transparent polymer electrode extends partially over the pixel-defining structure; and
the patterned auxiliary electrode extends over a portion of the patterned transparent polymer electrode and the pixel-defining structure.

8. The top-emitting pixel device of claim 7, wherein the pixel-defining structure comprises a bank structure separating at least the emissive layer of the top-emitting pixel device from an emissive layer of a second pixel device.

9. The top-emitting pixel device of claim 1, wherein:
the reflective bottom electrode comprises an anode;
the first charge transport layer comprises a hole transport layer;
the second charge transport layer comprises an electron transport layer; and
a combination of the patterned transparent polymer electrode and the patterned auxiliary electrode comprises a cathode.

10. The top-emitting pixel device of claim 9, wherein the patterned transparent polymer electrode of the cathode has an energy level in a range of −3.8 electron-volts (eV) to −4.7 eV.

11. The top-emitting pixel device of claim 1, wherein:
the reflective bottom electrode comprises a cathode;
the first charge transport layer comprises an electron transport layer;
the second charge transport layer comprises a hole transport layer; and
a combination of the patterned transparent polymer electrode and the patterned auxiliary electrode comprises an anode.

12. The top-emitting pixel device of claim 11, wherein the patterned transparent polymer electrode of the anode has an energy level in a range of −4.7 eV to −5.6 eV.

13. A display device comprising:
a substrate;
a pixel-defining structure defining a plurality of pixel regions over the substrate; and
an array of top-emitting pixel devices positioned over the substrate, each of the top-emitting pixel devices located within a corresponding one of the plurality of pixel regions and comprising:
a reflective bottom electrode disposed over the substrate;
a first charge transport layer disposed over the reflective bottom electrode;
an emissive layer disposed over the first charge transport layer;
a second charge transport layer disposed over the emissive layer;
a patterned transparent polymer electrode disposed over the second charge transport layer and extending laterally to cover an emissive area of the top-emitting pixel device; and
a patterned auxiliary electrode disposed at least partially over the patterned transparent polymer electrode outside of the emissive area of the top-emitting pixel device to make direct electrical contact with the patterned transparent polymer electrode,
the patterned transparent polymer electrodes and the patterned auxiliary electrodes of the display device forming a plurality of electrically separated conductive regions, each of the electrically separated conductive regions forming an electrode for at least one of the top-emitting pixel devices.

14. The display device of claim 13, wherein at least one of the electrically separated conductive regions forms an electrode for more than one of the top-emitting pixel devices.

15. The display device of claim 13, wherein at least two of the electrically separated conductive regions operate as in-cell touch panel electrodes.

16. The display device of claim 15, wherein the in-cell touch panel electrodes comprise:
a first portion of the electrically separated conductive regions operating as in-cell touch panel signal electrodes; and
a second portion of the electrically separated conductive regions operating as in-cell touch panel sensing electrodes.

17. A top-emitting pixel device comprising:
a reflective bottom anode disposed over a substrate;
a hole injection layer disposed over the reflective bottom anode;
a hole transport layer disposed over the hole injection layer;
an emissive layer disposed over the hole transport layer;
an electron transport layer disposed over the emissive layer and a pixel-defining structure at least partially surrounding the top-emitting pixel device; and
a transparent cathode disposed over the electron transport layer,
the hole injection layer comprising a patterned transparent conductive polymer that is electrically separated from the electron transport layer.

18. The top-emitting pixel device of claim 17, wherein the patterned transparent conductive polymer is crosslinked via an ultraviolet-activated crosslinking agent.

19. The top-emitting pixel device of claim 17, wherein the hole injection layer, the hole transport layer, and the emissive layer are patterned to prevent covering the pixel-defining structure.
